(19) United States
(12) Patent Application Publication
(10) Pub. No.: US 2010/0025850 A1
(43) Pub. Date: Feb. 4, 2010

(54) OHMIC ELECTRODE STRUCTURE AND SEMICONDUCTOR ELEMENT

(75) Inventors: Toshitaka Shimamoto, Osaka (JP); Kenji Yoshikawa, Okayama (JP); Kouji Makita, Hyogo (JP)

Correspondence Address: HAMRE, SCHUMANN, MUELLER & LARSON P.C., P.O. BOX 2902-0902, MINNEAPOLIS, MN, 55402, US

(73) Assignee: PANASONIC CORPORATION, Kadoma-shi, Osaka (JP)

(21) Appl. No.: 12/521,062

(22) PCT Filed: Feb. 21, 2008
(86) PCT No.: PCT/JP2008/000294

§ 371 Date: Jun. 24, 2009

(30) Foreign Application Priority Data
Mar. 28, 2007 (JP) 2007-083973

(51) Int. Cl. H01L 23/48; H01L 29/20

(52) U.S. Cl. 257/745; 257/751; 257/E23.01; 257/E29.089

(57) ABSTRACT

The present invention includes an AuGeNi alloy layer (13) provided on an n-type GaAs layer; and a laminate provided on the AuGeNi alloy layer (13), the laminate being composed of a bonding metal layer (15, 17) and a barrier metal layer (16, 18) provided on the bonding metal layer (15, 17). The present invention includes two or more of the laminates. With this configuration, in a GaAs-based contact layer, particularly in an n-type electrode, the surface diffusion of Ga of the semiconductor and Ni of the AuGeNi alloy, which is needed to form an ohmic contact in the n-type electrode, can be suppressed, and a low-resistance ohmic electrode structure and a semiconductor element having the ohmic electrode structure can be provided.

### TECHNICAL FIELD

The present invention relates to an ohmic electrode structure for an n-type GaAs semiconductor layer, and a semiconductor element using the electrode structure.

### BACKGROUND ART

An ohmic electrode is formed on an n-type GaAs layer of a compound semiconductor element such as a semiconductor laser or a GaAs-based IC. For the ohmic electrode, an AuGeNi alloy generally is used as a metal capable of achieving an ohmic contact. For forming an eutectic composition with Au, Ge is added so that it constitutes about 12% of AuGe of the ohmic electrode. Ge is captured at Ga lattice points in a GaAs layer by alloying (an alloying process), and becomes an n-type dopant. Thus, an energy barrier between the AuGeNi layer and the n-type GaAs layer is lowered, thereby enabling electron tunneling.

Ni of the AuGeNi alloy, on the other hand, is used to facilitate diffusion of Ge, which is an element having a slow diffusion rate. The diffusion of Ni reduces the chemical free energy of GaAs, and Ni itself becomes a p-type dopant for GaAs. Since Ni diffuses fast, attention should be given to the temperature and the time of alloying.

Examples of a device using such an electrode structure include a semiconductor laser. Semiconductor lasers have been used widely in many fields of electronics and optic-electronics, and are essential for optical devices. Currently, optical disc media such as CDs (compact discs) and DVDs (digital versatile discs) in particular have been used heavily as large-capacity recording media.

Furthermore, the recording speed has been increased along with an increase in the recording capacity. This trend is particularly noticeable in semiconductor lasers for CD and DVD. In order to increase the recording speed, it is necessary to enhance the power of semiconductor laser devices. In recent years, the market demands high-power infrared semiconductor laser devices for CD or red semiconductor laser devices for DVD of 200 to 300 mW or more.

In order to practically commercialize such high-power and high-speed optical devices, their operating current and operating voltage need to be reduced. To attain the reduction, it is necessary to achieve a low-resistance contact electrode having ohmic properties at a metal electrode interface with a semiconductor layer (see Patent document 1, for example).

Patent document 1 describes an electrode configured by providing an Ni layer (or an Au layer) on a semiconductor substrate, and forming two or more sets of a Pt layer and an Au layer on the Ni layer. This configuration is used as a p-type electrode on a nitride semiconductor.

Patent document 1: JP 2002-111061 A

### DISCLOSURE OF INVENTION

### Problem to be Solved by the Invention

As described above, Ga and Ni that have particularly large diffusion coefficients are diffused not only in a layer plane direction but also in a direction perpendicular to the layers. When Ga and Ni are diffused through the electrode and are segregated on the electrode surface, they form oxides, which cause problems such as abnormal contact with other parts, including deterioration in wire bonding strength.

In general, a topmost layer is formed with Au as an electrode material, and a gold wire is connected to the Au layer in many cases. In order to form an ohmic electrode on n-type GaAs, an alloying process (a heat treatment at 350° C. or more) is normally required. Ga and Ni are diffused significantly by the heat treatment, partly pass through the grain boundary of the Au layer present on the exposed surface, reach the electrode surface, and form oxides (e.g., Ga—O, Ni—O) on the surface. Since the oxides generally have high resistance, a high-resistance layer will be formed on the surface.

Further, when a wire is connected to the electrode in a state where Ga and Ni are segregated on the electrode surface, adhesion between the electrode and the wire drops, thereby causing a wire bonding failure.

Further, if Ni is diffused to the surface due to the heat treatment, an effect of facilitating the diffusion of Ge is weakened, and the contact resistance is increased.

Ni itself is present at the interface between the n-type GaAs substrate and the metal electrode layer, and serves to improve the adhesion. From the viewpoint of maintaining the adhesion, it is also necessary to suppress the surface diffusion of Ni.

In light of each of the problems described above, for forming an ohmic electrode for an n-type GaAs layer, alloying is carried out after an AuGeNi layer is formed, and further, a contact electrode additionally is formed on the AuGeNi layer, in many cases. In this case, the diffusion of Ni and Ga may be prevented by using a Pt layer, a Pd layer and a Ti layer in the contact electrode.

FIG. 6 is a schematic cross-sectional view showing a configuration of a conventional electrode formed on a semiconductor layer. An electrode composed of an n-type semiconductor layer 62, an AuGeNi alloy layer 63, Ni 64, a Ti layer 65 as a bonding metal layer, a Pt layer 66 as a barrier metal layer, and an Au layer 69 as an uppermost surface metal layer is formed on an n-type GaAs substrate 61.

As shown in FIG. 6, if the Pt layer 66 as a barrier metal layer is interposed between the AuGeNi alloy layer 63 and the Au layer 69 as the surface metal layer, the Pt layer 66 not only reduces a contact potential but also serves to prevent diffusion of other elements to the surface of the Au layer 69. Thus, this configuration is preferable in terms of maintaining the performance of the electrode.

In the electrode with the above configuration, however, it is necessary to thicken the barrier metal layer 66 in order to prevent the diffusion effectively. If the barrier metal 66 is thickened, a stress in the semiconductor layer 62 is increased during a high power operation in which a large amount of heat is particularly generated, thereby facilitating the occurrence of defects, which may cause deterioration of the device properties.

It is an object of the present invention to provide an ohmic electrode structure capable of suppressing, in an n-type electrode formed on a GaAs-based contact layer, the surface diffusion of Ga of the contact layer, and of Ni and the like of an AuGeNi alloy layer necessary to achieve an ohmic contact in the n-type electrode; and a semiconductor element including the ohmic electrode structure. Further, it is also an object of the present invention to provide an ohmic electrode structure that can provide such an effect without an increase in the internal stress; and a semiconductor element including the ohmic electrode structure.

### Means for Solving Problem

In order to solve the above problems, the ohmic electrode structure of the present invention includes: an AuGeNi alloy layer provided on an n-type GaAs layer; and a laminate provided on the AuGeNi alloy layer, the laminate being composed of a bonding metal layer and a barrier metal layer provided on the bonding metal layer. The ohmic electrode structure includes two or more of the laminates.

The semiconductor element of the present invention is provided with the ohmic electrode structure, and the semiconductor layer including the n-type GaAs layer has a film thickness of 80 μm or more and 120 μm or less.

### EFFECTS OF THE INVENTION

According to the present invention, by using an n-type electrode structure including two or more of laminates made of a metal material with high adhesivity (bonding metal layer: Ti, Ni, or the like) and a material with high barrier properties (barrier metal layer: Pt, Pd, or the like) on an n-type semiconductor layer, the barrier properties can be improved. Also, by forming a plurality of hetero interfaces between different electrode materials, the surface diffusion of Ga and Ni can be suppressed, and the occurrence of wire bonding failures and voids in the electrode can be suppressed. Thus, the resistance of the ohmic electrode structure can be reduced.

Furthermore, since sufficient effects can be obtained even if the bonding metal layers and the barrier metal layers are thin, internal stress in the ohmic electrode structure can be reduced by decreasing the film thickness of each layer.

### BRIEF DESCRIPTION OF DRAWINGS

FIG. 1 is a schematic cross sectional view showing an electrode metal layer in Embodiment 1 of the present invention.

FIG. 2 is a chart showing the experimental result concerning the film thickness dependence of contact resistivity of respective layers forming the electrode according to the embodiment.

FIG. 3 is a chart showing the experimental result concerning the relationship between the total film thickness of the electrode according to the embodiment and an amount of warpage of a wafer.

FIG. 4 is a chart showing the experimental result of the relationship between the thickness of each layer according to the embodiment of the present invention and stress occurring to the wafer.

FIG. 5 is a perspective view showing an integrated semiconductor laser device according to Embodiment 2 of the present invention as viewed from above.

FIG. 6 is a cross sectional view schematically showing a conventional electrode metal layer.

### DESCRIPTION OF REFERENCE NUMERALS

1 red semiconductor laser

2 infrared semiconductor laser

11, 31 n-type GaAs substrate

12 n-type semiconductor layer

13 AuGeNi alloy layer

14 Ni

15 first Ti layer

16 first Pt layer

17 second Ti layer

18 second Pt layer

19 Au layer

20 electrode metal layer

21-30 characteristic line

32 n-type cladding layer

33 active layer

34 first p-type cladding layer

35 etching stop layer

36 second p-type cladding layer

37 contact layer

38 insulating layer

39 p-type electrode

42 n-type cladding layer

43 active layer

44 first p-type cladding layer

45 etching stop layer

46 second p-type cladding layer

47 contact layer

48 insulating layer

49 p-type electrode

50 n-type electrode

51, 52 dielectric film

53 front end face

54 back end face

55 separation groove

### DESCRIPTION OF THE INVENTION

The ohmic electrode structure and the semiconductor element of the present invention, having the basic structure as described above, can be configured variously as follows.

The ohmic electrode structure of the present invention may be configured such that the barrier metal layer is made of Pt or Pd, and the bonding metal layer is made of Ti or Ni.

The ohmic electrode structure of the present invention also may be configured such that the laminate on the AuGeNi alloy layer is a first laminate; the bonding metal layer of the first laminate has a thickness of 100 nm or more; and the barrier metal layer of the first laminate is thinner than the bonding metal layer of the first laminate. Furthermore, the thickness of the barrier metal layer of the first laminate may be ½ or less of that of the bonding metal layer of the first laminate.

The ohmic electrode structure of the present invention may be configured such that the laminate on the AuGeNi alloy layer is a first laminate; assuming that the number of the laminates is ‘a’, the barrier metal layer of the a-th laminate has a thickness of 100 nm or more; and the bonding metal layer of the a-th laminate is thinner than the barrier metal layer of the a-th laminate. Furthermore, the thickness of the bonding metal layer of the a-th laminate may be ½ or less of that of the barrier metal layer of the a-th laminate.

The ohmic electrode structure of the present invention may be configured such that assuming that the number of the laminates is 3 or more, each of the bonding metal layers and each of the barrier metal layers interposed between the first laminate and the a-th laminate are thinner than the bonding metal layer of the first laminate and the barrier metal layer of the a-th laminate, respectively.

The ohmic electrode structure of the present invention may be configured so as to include an Au layer predominantly composed of Au on top of the laminates. The Au layer has a film thickness of 100 nm or more.

The semiconductor element of the present invention may further comprise a second electrode structure that is provided on a back side of the semiconductor element with respect to a side on which the ohmic electrode structure is provided. Furthermore, the second electrode structure includes at least one of Au, Pt and Ti.

The semiconductor element of the present invention may be configured such that the second electrode structure includes an Au layer predominantly composed of Au as an uppermost layer thereof, and the Au layer of the second electrode structure has a film thickness of 100 nm or more.

A semiconductor device of the present invention may be configured so as to include a plurality of the semiconductor elements, each of which includes the ohmic electrode structure, and the ohmic electrode structures are separated by a boundary region between the semiconductor elements. Furthermore, a semiconductor element of the present invention may be configured so as to include a plurality of the semiconductor elements, each of the semiconductor elements being provided with a plurality of the second electrode structures, and the second electrode structures are separated by a boundary region between the semiconductor elements.

The semiconductor element of the present invention may be configured such that a bonding metal material in the ohmic electrode structure and that in the second electrode structure are made of the same element and a barrier metal material in the ohmic electrode structure and that in the second electrode structure are made of the same element; and a sum of film thicknesses of the layers of the bonding metal material in the ohmic electrode structure and that in the second electrode structure are equal to each other, and a sum of film thicknesses of the layers of the barrier metal material in the ohmic electrode structure and that in the second electrode structure are equal to each other.

The semiconductor element of the present invention may be configured such that bonding metal materials in the ohmic electrode structure and in the second electrode structure are made of the same element and barrier metal materials in the ohmic electrode structure and in the second electrode structure are made of the same element; the second electrode structure includes a laminate in which the bonding metal material and the barrier metal material are laminated; and a sum of film thicknesses of the layers of the bonding metal material in the ohmic electrode structure and that in the second electrode structure are equal to each other, and a sum of film thicknesses of the layers of the barrier metal material in the ohmic electrode structure and that in the second electrode structure are equal to each other.

Hereinafter, embodiments of the present invention will be described with reference to the drawings.

### Embodiment 1

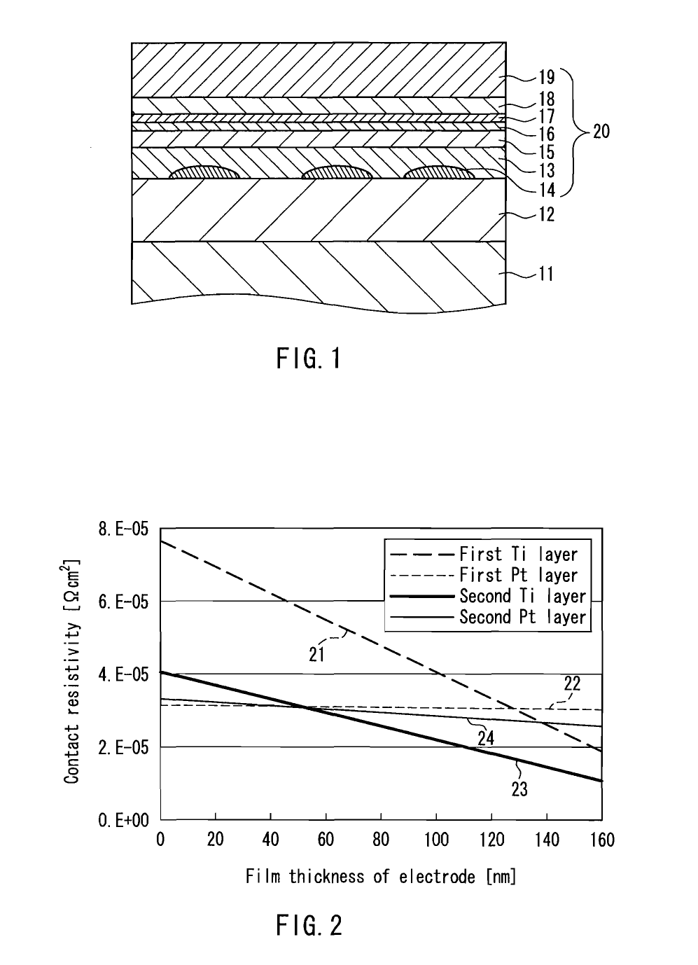

FIG. 1 is a schematic cross sectional view showing an electrode structure formed on a semiconductor layer in Embodiment 1 of the present invention. The electrode structure includes an n-type GaAs contact layer (n-type semiconductor layer) 12 and an electrode metal layer (electrode) 20 formed on the n-type semiconductor layer. The present embodiment will be described by referring to an n-type electrode.

In FIG. 1, the n-type semiconductor layer 12 as a layer to be in contact with the electrode metal layer 20 is formed on an n-type GaAs substrate 11. An AuGeNi alloy layer 13 is formed on the n-type semiconductor layer 12, and the AuGeNi alloy layer 13 includes Ni 14. A first Ti layer 15 as a bonding metal layer of a first laminate is formed on the AuGeNi alloy layer 13. A first Pt layer 16 as a barrier metal layer of the first laminate is formed on the first Ti layer 15. A second Ti layer 17 as a bonding metal layer of a second laminate is formed on the first Pt layer 16. A second Pt layer 18 as a barrier metal layer of the second laminate is formed on the second Ti layer 17. An Au layer 19 as an uppermost surface metal layer is formed on the second Pt layer 18. The electrode according to the present embodiment includes two or more such laminates, each of which is composed of a bonding metal layer and a barrier metal layer.

Next, a method of manufacturing the electrode according to the present embodiment will be described. First, the n-type semiconductor layer 12 is crystal-grown on the n-type GaAs substrate 11 by metal-organic vapor-phase epitaxy (MOVPE). Si is used as an n-type dopant. It should be noted that the present invention relates to an electrode for an n-type semiconductor, and thus the layer structure of the semiconductor substrate side is not particularly limited. Further, a method other than metal-organic vapor-phase epitaxy can be used to grow crystals.

The surface of the n-type semiconductor layer 12 formed in the above manner is cleaned with an organic solvent such as acetone or methanol. After the surface is dried, the electrode metal layer 20 is formed on the n-type semiconductor layer 12 by electron beam evaporation, spattering, and the like.

To form the electrode metal layer 20, first, the AuGeNi alloy layer 13, which is essential in achieving an ohmic contact, is formed. The thickness of the AuGeNi alloy layer 13 is not particularly specified. The Ni 14 within the AuGeNi alloy layer 13 can be oxidized very easily. Thus, when the AuGeNi layer comes into contact with air, the Ni is oxidized and increases the resistance. In order to prevent the Ni from being oxidized, a thin Au layer (not shown) of about 50 to 100 μm may be provided on the AuGeNi alloy layer. However, in the case where the AuGeNi alloy layer 13 is formed and thereafter an electrode structure is formed successively thereon, it is not necessary to provide the Au layer. When the Ni 14 in the AuGeNi alloy layer 13 is thin, the Ni 14 is not in a flat shape but in an island shape.

Subsequently, the first Ti layer 15 having a thickness of 100 nm, the first Pt layer 16 having a thickness of 50 nm, the second Ti layer 17 having a thickness of 50 nm, and the second Pt layer 18 having a thickness of 100 nm are laminated in that order on the AuGeNi alloy layer 13.

Although Ti is used as the material for the bonding metal layer in the present embodiment, Ni also may be used, which has a high work function and an adhesivity similar to that of Ti. Further, although Pt is used as the material for the barrier metal layer, Pd may also be used, which has high barrier properties.

Next, the Au layer 19 as the exposed surface is formed on the second Pt layer 18. The Au layer 19 needs to have a thickness of 100 nm or more in order to withstand contact with a wiring during wire bonding. When the Au layer 19 is thin, the adhesion during the wire bonding deteriorates, and wire bonding failure occurs. Through the above process, the electrode metal layer 20 is formed.

After forming the electrode metal layer 20, a heat treatment is carried out on the electrode metal layer 20 in an annealing furnace. It is desirable that the heat treatment is carried out in an atmosphere of nitrogen as an inert gas. It is preferable that the temperature of the heat treatment is in a range of 350° C. to 450° C. If the temperature exceeds 450° C., it may affect the n-type semiconductor layer 12. This heat treatment allows Ge in the AuGeNi alloy layer 13 to be captured into the n-type semiconductor layer 12, thereby lowering an energy barrier between the n-type semiconductor layer 12 and the AuGeNi alloy layer 13. Through the above process, the electrode according to the present embodiment is formed.

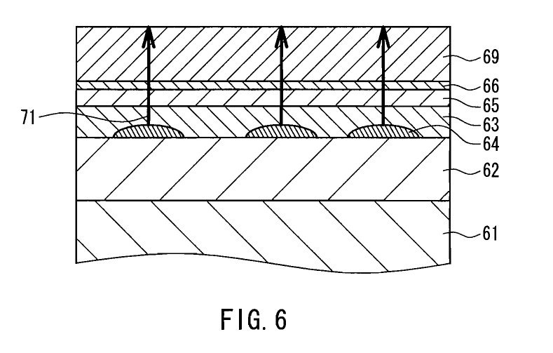

Hereinafter, effects obtained by the configuration of the ohmic electrode structure according to the present embodiment will be described. In the case of a conventional Ti/Pt/Au laminate structure that includes one laminate of a bonding metal layer and a barrier metal layer as shown in FIG. 6, if the heat treatment as described above is carried out, elements such as Ni of the Ni 64, which is in an island shape, and Ga pass (in arrow 71 direction) through grain boundaries of other electrode material layers and reach the surface. Here, a grain boundary refers to a space between crystal grains. Then, the portions from which Ni or Ga moved away (cavitation) become pinholes. Thus, the contact area of the electrode is narrowed, thereby resulting in an increase in contact resistance at the interface between the electrode metal and the semiconductor.

Generally, a reduction in the driving voltage and driving current of semiconductor devices is required. To reduce the driving voltage and driving current the resistance of the electrode may be reduced. In order to reduce the resistance of the electrode, it is necessary to prevent the cavitation and to prevent a current injection path from being biased.

Diffusion of Ni and Ga during the heat treatment can be suppressed significantly at the interfaces between layers formed of different elements. By adopting a multilayer structure in which Ti layers and Pt layers are laminated repeatedly so as to utilize such a characteristic, the surface diffusion of Ni and Ga due to the heat treatment can be suppressed, and the formation of pinhole-like cavities can be prevented. The electrode according to the present embodiment is configured by forming two or more laminates of a metal material having high adhesivity (Ti, Ni, or the like) and a material having high barrier properties (Pt, Pd, or the like) on the n-type semiconductor layer 12.

FIG. 2 is a chart showing the experimental result concerning the film thickness dependence of contact resistivity of respective layers forming the electrode. Characteristic lines 21 to 24 indicate the film thickness dependence of contact resistivity of the first Ti layer 15, the first Pt layer 16, the second Ti layer 17 and the second Pt layer 18, respectively. In FIG. 2, the characteristic line 21 has a greater slope than the characteristic lines 22 to 24. That is, the contact resistivity depends most on the thickness of the first Ti layer 15, and the experiment proved that the contact resistivity can be reduced by thickening the first Ti layer 15. From the n-type semiconductor layer 12 and the AuGeNi alloy layer 13, the first Ti layer 15 is the first layer of the laminate structure composed of a Ti layer and a Pt layer (such a laminate composed of a Ti layer and a Pt layer is hereinafter referred to as a “Ti/Pt laminate”). Thus, it is considered that the first Ti layer 15 improves the adhesion as well as serves as a barrier layer against the diffusion from the semiconductor layer 12 and the AuGeNi alloy layer 13.

In order to demonstrate this by an experiment, an Auger electron spectroscopy analysis (AES) was carried out on the electrode according to the present embodiment. The result reveals that the first Ti layer 15 can suppress the diffusion of Ga and Ni. In contrast, the result also shows that when Auger electron spectroscopy analysis is carried out on the first Ti layer with its thickness decreased to 50 nm, Ga and Ni are diffused to the surface side. From the above findings, it can be concluded that the first Ti layer 15 can act as a diffusion prevention layer when it is formed to be 100 nm or more in thickness.

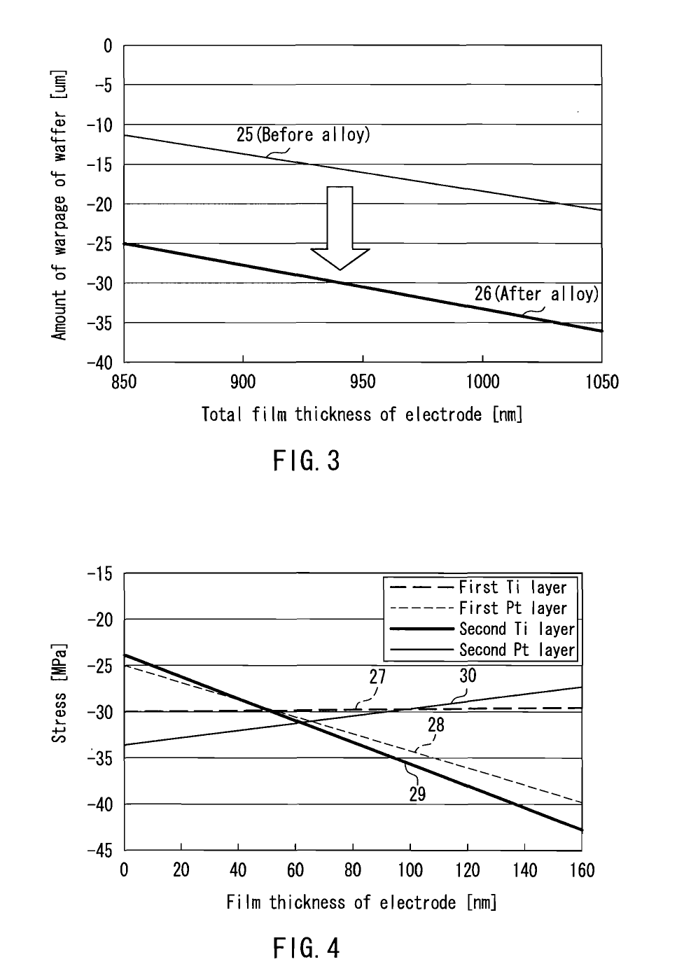

Next, an experiment was carried out to evaluate an amount of warpage at the wafer level. FIG. 3 is a chart showing the experimental result concerning the relationship between the total film thickness of the electrode and an amount of warpage of a wafer (the n-type GaAs substrate 11 and the n-type semiconductor layer 12). In FIG. 3, a characteristic line 25 indicates the amount of warpage of the wafer before the heat treatment (alloying), and a characteristic line 26 indicates the amount of warpage of the wafer after the heat treatment (alloying). By carrying out the heat treatment (alloying), the amount of warpage of the wafer further is increased compared to the amount before the alloying. Further, the amount of warpage of the wafer is increased as the total film thickness is increased. Since the heat treatment (alloying) is essential in reducing the contact resistivity, it is very difficult to eliminate the heat treatment process. Thus, in order to reduce the amount of warpage of the wafer and to reduce a stress applied to the device, it is necessary to make each layer as thin as possible so as to decrease the total film thickness.

FIG. 4 is a chart showing the experimental result of the relationship between the thickness of each layer and a stress that occurred in the wafer. Characteristic lines 27 to 30 indicate stresses that occurred in the wafer due to the first Ti layer 15, the first Pt layer 16, the second Ti layer 17 and the second Pt layer 18, respectively. In FIG. 4, the characteristic lines 28 and 29 have greater slopes than the characteristic lines 27 and 30. That is, the stress in the wafer is affected significantly by particularly the film thicknesses of the first Pt layer 16 and the second Ti layer 17. Thus, the first Pt layer 16 and the second Ti layer 17 may be formed to be thinner than the other layers so as to reduce the stress in the wafer. In the electrode according to the present embodiment, each of the first Ti layer 15 and the second Pt layer 18 has a film thickness of 100 nm, and each of the first Pt layer 16 and the second Ti layer 17 has a film thickness of 50 nm. Therefore, the stress in the wafer can be reduced further as compared with the case where the film thickness of each layer is almost the same.

As described above, by configuring the electrode according to the present embodiment so that the electrode includes two Ti/Pt laminates, it is possible to provide a low-resistance ohmic electrode whose resistivity does not increase even after the heat treatment (alloying).

Further, by setting the thicknesses of the first Ti layer 15, the first Pt layer 16, the second Ti layer 17 and the second Pt layer 18 to 100 nm, 50 nm, 50 nm, and 100 nm respectively, the stress in the wafer after the heat treatment can be reduced. The reduction of the stress suppresses the occurrence of defects in the semiconductor substrate, thereby ensuring the reliability during a high power operation.

Due to these effects, the electrode according to the present embodiment has a total film thickness of about 910 to 1010 nm, including the Au layer 19 as the metal surface of the uppermost layer. The lift-off properties at the time of forming the electrode however is still excellent, and roughness is not found on the electrode surface after the alloying.

The surface diffusion of Ga and Ni also is suppressed during a heat treatment for the alloying process. Thus, an electrode having excellent adhesivity and ohmic properties can be formed, and stabilization and simplification of the semiconductor process can be achieved.

By using such an electrode, low-resistance contacts can be achieved without loss of the device properties. As a result, the reliability of the device can be ensured while the driving voltage and the driving current are reduced.

Although the present embodiment is described by referring to the case of two Ti/Pt laminates, the number of the laminates is not limited to two. In the case of a (a is 3 or more) Ti/Pt laminates, it is desirable that each of the Ti layers and each of the Pt layers interposed between the first laminate and the a-th laminate (hereinafter referred to as intermediate layers) are formed to be thinner than the first Ti layer and the a-th Pt layer, respectively. Since there is a tendency for stress to be increased significantly as the film thickness of the intermediate layer increases, as compared with the first Ti layer and the a-th Pt layer (see FIG. 4), it is desirable to reduce the thicknesses to about 50 nm.

By adopting the electrode structure of the present embodiment as described above, and forming a plurality of hetero interfaces between different electrode materials, the surface diffusion of Ga and Ni can be suppressed, and a wire bonding failure can be prevented. Thereby an electrode structure having excellent adhesivity and ohmic properties can be formed, whereby an increase in the contact resistance can be suppressed. Furthermore, by optimally setting the film thickness of each of the bonding metal layers (first Ti layer 15, second Ti layer 17) and the barrier metal layers (first Pt layer 16, second Pt layer 18), a stress resulting from the electrode can be reduced, and thereby low-resistance contacts can be achieved without the device properties impaired.

Since the present embodiment relates to an electrode for an n-type semiconductor, there is no particular restriction to an electrode on the p-type semiconductor side. Further, although the present embodiment is described by referring to formation of an electrode on an n-type GaAs contact layer, the electrode can be configured similarly even on a layer made with another material system (e.g., GaN-based material). Even if another material system is used, the barrier properties can be improved by forming two or more laminates, each of which includes a layer of a metal material having high adhesivity (bonding metal layer) and a layer of a material having high barrier properties (barrier metal layer) on an n-type semiconductor layer. Also, by forming a plurality of hetero interfaces between different electrode materials, the surface diffusion of Ga can be suppressed, and wire bonding failures and the occurrence of voids in the electrode can be suppressed.

### Embodiment 2

A semiconductor device according to Embodiment 2 of the present invention includes electrodes formed on both the front face and the back face of the semiconductor device. Examples of a semiconductor device with such a configuration include a dual-wavelength semiconductor laser device. Hereinafter, the following specifically describes the present embodiment by referring to a dual-wavelength semiconductor laser device.

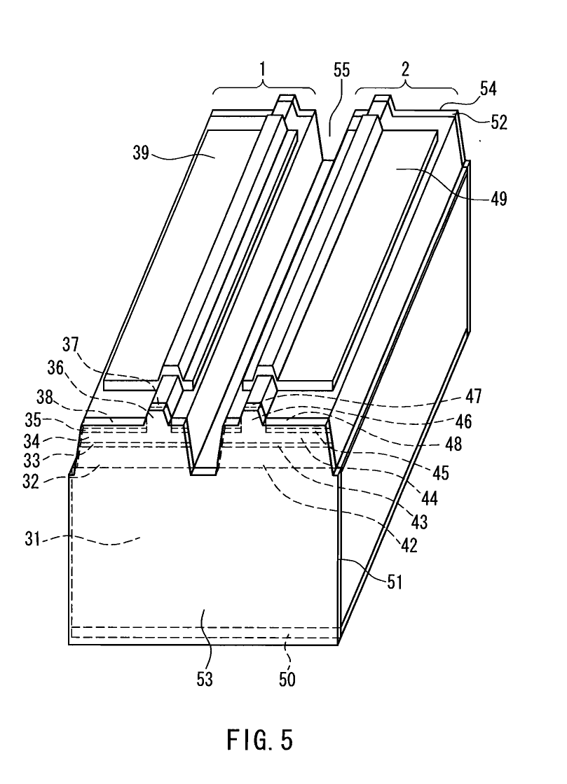

FIG. 5 is a perspective view showing the dual-wavelength semiconductor laser device according to the present embodiment as viewed from above. The dual-wavelength semiconductor laser device according to the present embodiment includes a red semiconductor laser 1 having an oscillation wavelength at a band of 660 nm and an infrared semiconductor laser 2 having an oscillation wavelength at a band of 780 nm, both of which are formed on the same substrate.

As shown in FIG. 5, the dual-wavelength semiconductor laser device of Embodiment 2 includes the red semiconductor laser 1 and the infrared semiconductor laser 2, which are formed integrally on an n-type GaAs substrate 31. The red semiconductor laser 1 includes an n-type cladding layer 32, an active layer 33, a first p-type cladding layer 34, an etching stop layer 35, a second p-type cladding layer 36, a contact layer 37 and an insulating layer 38 laminated in that order on the n-type GaAs substrate 31.

The infrared semiconductor laser 2 has a configuration similar to that of the red semiconductor laser 1, and includes an n-type cladding layer 42, an active layer 43, a first p-type cladding layer 44, an etching stop layer 45, a second p-type cladding layer 46, a contact layer 47 and an insulating layer 48 laminated in that order on the n-type GaAs substrate 31.

The insulating layer 38 covers the side faces of a ridge stripe structure that is a convex part having a trapezoid shape formed on the second p-type cladding layer 36, and the top face of the etching stop layer 35. The shape of the ridge stripe structure is not limited to a trapezoid shape, and it may be a rectangular shape having sides that rise substantially perpendicularly (parallelepiped shape). The insulating layer 38 is not formed on the top face of the ridge stripe structure of the second p-type cladding layer 36. A p-type electrode 39 is disposed on the top face of the ridge stripe structure, so that a carrier (hole) can be injected into the ridge stripe structure. A p-type electrode 49 is disposed similarly on the infrared semiconductor laser 2 side.

An n-type electrode 50 is disposed on a back side of the n-type GaAs substrate 31 with respect to a side on which the p-type electrodes 39 and 49 are provided. Two end faces in a direction orthogonal to the ridge strip structure of the second p-type cladding layer 36, which form a resonator together, are coated with dielectric films 51 and 52 respectively, whereby an output surface (front end face) 53 from which a laser beam is output, and a back end face 54 positioned on the opposite side to the output surface 53, are formed.

A separation groove 55 is provided to separate the red semiconductor laser 1 and the infrared semiconductor laser 2 electrically. By separating at least one of the p-type electrodes 39 and 49 and the n-type electrode 50 at the boundary region (the separation groove) between the semiconductor elements, and applying a bias to the electrodes separately, each laser can be operated individually. In the example shown in FIG. 5, a pair of the p-type electrodes 39 and 49 is separated, and the n-type electrode 50 is a common electrode. That is, the p-type electrodes 39 and 49 may have the same laminate structure, which will be described below.

Examples of the structure of the p-type electrodes 39 and 49 that make an ohmic contact with the contact layers 37 and 47 include a Ti/Pt/Au laminate structure. In the p-type electrodes 39 and 49 having a Ti/Pt/Au laminate structure, a Ti layer as a bonding metal layer, a Pt layer as a barrier metal layer and an Au layer as a surface metal are formed to be 50 to 200 nm, 50 to 200 nm, and 100 nm or more in thickness, respectively.

In the case of end face output type semiconductor laser, it is necessary to create a mirror face by cleavage. Since the cleavage properties deteriorate when the substrate is thick, the semiconductor substrate is thinned to 80 μm to 120 μm by etching or grinding.

The n-type electrode 50 has an AuGeNi/Ti/Pt/Ti/Pt/Au structure as shown in Embodiment 1, and is formed on the back of the n-type GaAs substrate 31. In the case where the n-type GaAs substrate 31 is thinned, a large stress occurs in the wafer and warpage takes place when a heat treatment is carried out on the electrode.

At this time, it is desirable that the same element is used as the bonding metal material (Ti in this example) in the p-type electrodes 39 and 49, and as that in the n-type electrode 50, and that the film thicknesses are set so that a sum of the film thicknesses of the layers of the bonding metal material in the p-type electrodes 39 and 49, and that of the n-type electrode 50 are substantially equal to each other. Similarly, it is desirable that the same element is used as the barrier metal material (Pt in this example) in each of the p-type electrodes 39 and 49, and as that in the n-type electrode 50, and that the film thicknesses are set so that a sum of film thicknesses of the layers of the barrier metal material in each of the p-type electrodes 39 and 49, and that of the n-type electrode 50 are substantially equal to each other.

Furthermore, for the p-type electrodes 39 and 49, similarly to the n-type electrode 50, the bonding metal material and the barrier metal material may be laminated so as to form a plurality of laminates. For example, ohmic electrodes with respect to the contact layers 37 and 47 have a Ti/Pt/Au structure, and the n-type electrode 50 has a Ti/Pt/Ti/Pt/Au structure. Further, the film thicknesses may be set so that a sum of film thicknesses of the layers of the bonding metal material (Ti in this example) and that of the barrier metal material (Pt in this example) in each of the p-type electrodes, and those of the n-type electrode are substantially equal to each other, respectively. By adopting a multilayer structure in which Ti layers and Pt layers are laminated repeatedly, the surface diffusion of Ga due to the heat treatment can be suppressed, and formation of pinhole-like cavities can be prevented. Also with this structure, a low-resistance electrode can be obtained.

Since stresses resulting from electrode materials can be canceled between the front face and the back face of the substrate, a stress present in the device can be reduced. In the case of a semiconductor laser, by reducing a stress (distortion) present in the chip against the active layer, the occurrence of defects at the time of driving the laser can be suppressed, whereby the reliability can be improved.

### INDUSTRIAL APPLICABILITY

The present invention provides an ohmic electrode for an n-type GaAs semiconductor, and a semiconductor element using the same. They are applicable to electronic devices and the like in addition to semiconductor lasers.

1. An ohmic electrode structure comprising:
an AuGeNi alloy layer provided on an n-type GaAs layer; and
a laminate provided on the AuGeNi alloy layer, the laminate being composed of a bonding metal layer and a barrier metal layer provided on the bonding metal layer,
wherein the ohmic electrode structure includes two or more of the laminates.

2. The ohmic electrode structure according to claim 1,
wherein the barrier metal layer is made of Pt or Pd, and
the bonding metal layer is made of Ti or Ni.

3. The ohmic electrode structure according to claim 1,
wherein the laminate on the AuGeNi alloy layer is a first laminate,
the bonding metal layer of the first laminate has a thickness of 100 nm or more, and
the barrier metal layer of the first laminate is thinner than the bonding metal layer of the first laminate.

4. The ohmic electrode structure according to claim 3, wherein the thickness of the barrier metal layer of the first laminate is ½ or less of that of the bonding metal layer of the first laminate.

5. The ohmic electrode structure according to claim 1,
wherein the laminate on the AuGeNi alloy layer is a first laminate,
assuming that the number of the laminates is ‘a’, the barrier metal layer of the a-th laminate has a thickness of 100 nm or more, and
the bonding metal layer of the a-th laminate is thinner than the barrier metal layer of the a-th laminate.

6. The ohmic electrode structure according to claim 5, wherein the thickness of the bonding metal layer of the a-th laminate is ½ or less of that of the barrier metal layer of the a-th laminate.

7. The ohmic electrode structure according to claim 5, wherein assuming that the number of the laminates is 3 or more, each of the bonding metal layers and each of the barrier metal layers interposed between the first laminate and the a-th laminate are thinner than the bonding metal layer of the first laminate and the barrier metal layer of the a-th laminate, respectively.

8. The ohmic electrode structure according to claim 1 further comprising an Au layer predominantly composed of Au on top of the laminates,
wherein the Au layer has a film thickness of 100 nm or more.

9. A semiconductor element comprising the ohmic electrode structure according to claim 1,
wherein a semiconductor layer including the n-type GaAs layer has a film thickness of 80 μm or more and 120 μm or less.

10. The semiconductor element according to claim 9, further comprising a second electrode structure, the second electrode structure being provided on a back side of the semiconductor element with respect to a side on which the ohmic electrode structure is provided.

11. The semiconductor element according to claim 10, wherein the second electrode structure includes at least one of Au, Pt and Ti.

12. The semiconductor element according to claim 10, wherein the second electrode structure includes an Au layer predominantly composed of Au as an uppermost layer thereof, and the Au layer of the second electrode structure has a film thickness of 100 nm or more.

13. A semiconductor device comprising a plurality of the semiconductor elements according to claim 9, each of the semiconductor elements being provided with the ohmic electrode structure,
wherein the ohmic electrode structures are separated by a boundary region between the semiconductor elements.

14. A semiconductor device comprising a plurality of the semiconductor elements according to claim 10, each of the semiconductor elements including a plurality of the second electrode structures,
wherein the second electrode structures are separated by a boundary region between the semiconductor elements.

15. The semiconductor element according to claim 10,
wherein a bonding metal material in the ohmic electrode structure and a bonding metal material in the second electrode structure are made of the same element, and a barrier metal material in the ohmic electrode structure and a barrier metal material in the second electrode structure are made of the same element, and
a sum of film thicknesses of the layers of the bonding metal material in the ohmic electrode structure and that in the second electrode structure are equal to each other, and a sum of film thicknesses of the layers of the barrier metal material in the ohmic electrode structure and that in the second electrode structure are equal to each other.

16. The semiconductor element according to claim 10,
wherein a bonding metal material in the ohmic electrode structure and a bonding metal material in the second electrode structure are made of the same element, and a barrier metal material in the ohmic electrode structure and a barrier metal material in the second electrode structure are made of the same element,
the second electrode structure includes a laminate in which the bonding metal material and the barrier metal material are laminated, and
a sum of film thicknesses of the layers of the bonding metal material in the ohmic electrode structure and that in the second electrode structure are equal to each other, and a sum of film thicknesses of the layers of the barrier metal material in the ohmic electrode structure and that in the second electrode structure are equal to each other.
